(19) United States
(12) Patent Application Publication
(10) Pub. No.: US 2022/0271199 A1
(43) Pub. Date: Aug. 25, 2022

(54) NITRIDE SEMICONDUCTOR ELEMENT

(71) Applicant: Nichia Corporation, Anan-shi (JP)

(72) Inventor: Hiroki KONDO, Anan-shi (JP)

(73) Assignee: Nichia Corporation, Anan-shi (JP)

(21) Appl. No.: 17/736,790

(22) Filed: May 4, 2022

Related U.S. Application Data
(63) Continuation of application No. PCT/JP2020/043810, filed on Nov. 25, 2020.

(30) Foreign Application Priority Data
Nov. 26, 2019 (JP) 2019-213474
Jul. 20, 2020 (JP) 2020-123823

(51) Int. Cl. H01L 33/32; H01L 33/06

(52) U.S. Cl. CPC H01L 33/32; H01L 33/06

(57) ABSTRACT

A nitride semiconductor element includes: an n-side nitride semiconductor layer; an active layer located on the n-side nitride semiconductor layer, the active layer comprising a plurality of well layers formed of a nitride semiconductor and a plurality of barrier layers formed of a nitride semiconductor; and a p-side nitride semiconductor layer located on the active layer. The plurality of well layers includes, in order from the n-side nitride semiconductor layer side: one or more first intermediate layers containing Al, Ga, and N, a second intermediate layer containing Ga and N, and a light emitting layer containing Ga and N and adapted to emit ultraviolet light.

### CROSS-REFERENCE TO RELATED APPLICATIONS

This application is a bypass continuation of PCT Application No. PCT/JP2020/043810, filed on Nov. 25, 2020, which claims priority to Japanese Patent Application No. 2019-213474, filed on Nov. 26, 2019, and Japanese Patent Application No. 2020-123823, filed on Jul. 20, 2020, the disclosures of which are hereby incorporated by reference in their entireties.

### BACKGROUND

The present invention relates to nitride semiconductor elements.

In recent years, the development of light emitting elements that emit ultraviolet light has been actively pursued. For example, JP 2017-175005 A discloses a light emitting element that has a multiple quantum well structure suitable for emission of deep ultraviolet light. Near-ultraviolet light emitting elements have also been developed for resin curing and various sensing applications.

### SUMMARY

Nitride semiconductor elements that emit ultraviolet light have been modified to improve their characteristics, for example, an emission output or the like, but their characteristics have not yet been enhanced sufficiently.

Therefore, an object of certain embodiments of the present invention is to provide a nitride semiconductor element that emits ultraviolet light with a high emission output.

According to one embodiment, a nitride semiconductor element includes: an n-side nitride semiconductor layer; an active layer provided on the n-side nitride semiconductor layer, the active layer including a plurality of well layers formed of a nitride semiconductor and a plurality of barrier layers formed of a nitride semiconductor; and a p-side nitride semiconductor layer provided on the active layer. The plurality of well layers includes, in order from the n-side nitride semiconductor layer side: a first intermediate layer having a smaller band gap energy than the barrier layer and containing Al, Ga, and N, a second intermediate layer having a smaller band gap energy than the first intermediate layer and containing Ga and N, and a light emitting layer having a smaller band gap energy than the first intermediate layer and containing Ga and N, the well layer emitting ultraviolet light. A thickness of the first intermediate layer is less than a thickness of each of the second intermediate layer and the light emitting layer. Of the plurality of barrier layers, the barrier layer disposed between the second intermediate layer and the light emitting layer is doped with n-type impurities.

According to certain embodiments of the present invention, a nitride semiconductor element that emits ultraviolet light with a high emission output can be provided.

### BRIEF DESCRIPTION OF THE DRAWINGS

FIG. 1 is a cross-sectional view showing a configuration of a nitride semiconductor element disposed on a substrate, according to an embodiment of the present invention.

FIG. 2 is a diagram of a multiple quantum well structure of the nitride semiconductor element shown in FIG. 1.

FIG. 3 is a diagram of band gap energies in the multiple quantum well structure shown in FIG. 2.

FIG. 4 is a cross-sectional view of a prepared first substrate in a method of manufacturing a light emitting device of an embodiment of the present invention.

FIG. 5 is a cross-sectional view of formation of an n-side nitride semiconductor layer on an upper surface of the prepared first substrate in the method of manufacturing a light emitting device of the embodiment of the present invention.

FIG. 6 is a cross-sectional view of formation of an active layer on the n-side nitride semiconductor layer formed on the upper surface of the first substrate in the method of manufacturing a light emitting device of the embodiment of the present invention.

FIG. 7 is a cross-sectional view of a first wafer obtained by forming a p-side nitride semiconductor layer on the active layer formed on the upper surface of the first substrate via the n-side nitride semiconductor layer in the method of manufacturing a light emitting device of the embodiment of the present invention.

FIG. 8 is a cross-sectional view of formation of a resist for forming second electrodes, on the p-side nitride semiconductor layer of the first wafer in the method of manufacturing a light emitting device of the embodiment of the present invention.

FIG. 9 is a cross-sectional view of formation of a metal film for forming the second electrodes, on the p-side nitride semiconductor layer of the first wafer in the method of manufacturing a light emitting device of the embodiment of the present invention.

FIG. 10 is a cross-sectional view of formation of the second electrodes having a predetermined shape by removing the resist formed on the p-side nitride semiconductor layer of the first wafer together with the metal film formed on the resist in the method of manufacturing a light emitting device of the embodiment of the present invention.

FIG. 11 is a cross-sectional view of formation of a resist on the second electrodes in order to form an insulating film between the second electrodes on the p-side nitride semiconductor layer of the first wafer in the method of manufacturing a light emitting device of the embodiment of the present invention.

FIG. 12 is a cross-sectional view of formation of the insulating film on the resist and between the second electrodes on the p-side nitride semiconductor layer of the first wafer in the method of manufacturing a light emitting device of the embodiment of the present invention.

FIG. 13 is a cross-sectional view of formation of the second electrodes and the insulating film on the p-side nitride semiconductor layer of the first wafer by removing the resist together with portions of the insulating film formed on the resist in the method of manufacturing a light emitting device of the embodiment of the present invention.

FIG. 14 is a cross-sectional view of formation of a metal film on the second electrodes and the insulating film formed on the p-side nitride semiconductor layer of the first wafer in the method of manufacturing a light emitting device of the embodiment of the present invention.

FIG. 15 is a cross-sectional view of preparation of a second substrate with a metal layer formed on one surface thereof and positioning of the first wafer to face the second substrate in the method of manufacturing a light emitting device of the embodiment of the present invention.

FIG. 16 is a cross-sectional view of joining between the first wafer and the second substrate by joining the metal layers to each other in the method of manufacturing a light emitting device of the embodiment of the present invention.

FIG. 17 is a cross-sectional view of a second wafer fabricated in the method of manufacturing a light emitting device of the embodiment of the present invention.

FIG. 18 is a cross-sectional view of removal of portions of a nitride semiconductor element in the second wafer fabricated in the method of manufacturing a light emitting device of the embodiment of the present invention.

FIG. 19 is a cross-sectional view of formation of first electrodes with a predetermined pattern on the n-side nitride semiconductor layer of the second wafer in the method of manufacturing a light emitting device of the embodiment of the present invention.

FIG. 20 is a diagram showing a multiple quantum well structure of a nitride semiconductor element according to a modification of the present invention.

### DETAILED DESCRIPTION

Embodiments and examples of the present invention will be described with reference to the drawings. Embodiments of a nitride semiconductor element described below are intended to embody the technical ideas of the present invention; however the present invention is not limited to the described embodiments and examples, unless otherwise stated.

In each drawing, members having the same function may be denoted by the same reference numeral. The present invention may be described by being divided into embodiments or examples for convenience in consideration of ease of explanation or understanding of the main points thereof, but partial substitutions or combinations of configurations described in different embodiments and examples are possible. In the following embodiments and examples, the repeated description of matters common to preceding embodiments or examples will be omitted, and only the differences between the preceding and present embodiments and examples will be described. In particular, the same operations and effects achieved by the same configuration will not be repeated for each embodiment and example. The size, positional relationship, and the like of members shown in the figures may be exaggerated to clarify the description thereof.

A semiconductor structure used in a light emitting diode includes an n-side nitride semiconductor layer of an n-type, a p-side nitride semiconductor layer of a p-type, and an active layer provided between the n-side nitride semiconductor and the p-side nitride semiconductor. The active layer uses, for example, a multiple quantum well structure that includes a plurality of well layers. In general, in a light emitting diode that emits ultraviolet light and includes a plurality of well layers in an active layer, a well layer located close to a p-side nitride semiconductor layer of the plurality of well layers tends to contribute to light emission, while a well layer located close to an n-side nitride semiconductor layer tends not to contribute to light emission. The well layer located close to the n-side nitride semiconductor layer could absorb (self-absorb) light emitted from the well layer located close to the p-side nitride semiconductor layer, which may deteriorate light extraction efficiency.

Accordingly, the present inventors have conducted intensive studies focusing on the recombination probability of electrons and holes, lattice relaxation in crystals of a semiconductor layer, and self-absorption of light by the semiconductor layer as factors affecting an emission output from a nitride semiconductor element.

First, the present inventors have performed a study on a technique for reducing the self-absorption of light in the plurality of well layers. The self-absorption of light in the well layers is reduced as the band gap energy of the semiconductor layer forming the well layer becomes larger. Thus, the present inventors have performed a study based on the fact that the self-absorption of light in the active layer is reduced by making the band gap energy of the well layer (intermediate layer) not contributing to the light emission and located close to the n-side nitride semiconductor layer larger than the band gap energy of the well layer contributing to the light emission and located close to the p-side nitride semiconductor layer.

The nitride semiconductor element including a plurality of well layers configured in this way have been expected to exhibit higher emission output than that in a conventional nitride semiconductor element, but in fact cannot obtain sufficiently high emission output.

The present inventors have continuously studied this result and hypothesized that the reason that the emission output cannot be improved sufficiently is that the improvement in the emission output is inhibited by the lattice relaxation in crystals between the light emitting layer, which is the well layer contributing to the light emission, and the intermediate layer, due to a difference in the composition between the light emitting layer and the intermediate layer. Based on this hypothesis, the present inventors have achieved an improvement in the emission output by disposing, between the light emitting layer and the intermediate layer (first intermediate layer), a second intermediate layer having a smaller band gap energy than the first intermediate layer, in order to suppress the lattice relaxation compared to the case where no second intermediate layer is provided.

Further study has been made in order to obtain higher emission output in a nitride semiconductor element that includes the first intermediate layer having a large band gap energy, the second intermediate layer having a smaller band gap energy than the first intermediate layer, and the light emitting layer in order from the n-side nitride semiconductor layer side. As a result, the following findings have been made.

(1) By making the thickness of the first intermediate layer less than the thickness of each of the second intermediate layer and the light emitting layer, self-absorption in the first intermediate layer of light emitted in the light emitting layer can be more effectively suppressed.

(2) By doping a barrier layer between the light emitting layer and the second intermediate layer with n-type impurities, recombination in the light emitting layer can be further promoted.

Here, it is preferable that the light emitting layer is formed by a layer containing Ga and N in consideration of the recombination probability of electrons and holes, and that a predetermined emission wavelength of the well layer is set mainly by adjusting the composition ratio of In, Ga and N.

Further, it is preferable that the first intermediate layer is formed by a layer containing Al, Ga, and N, and that the band gap energy of the first intermediate layer is larger than the band gap energy of light emitting mainly by adjusting the composition ratio of Al, Ga and N. Thus, the self-absorption of light in the first intermediate layer can be suppressed effectively.

Furthermore, the second intermediate layer is formed by a layer containing Ga and N, and the band gap energy of the second intermediate layer is set smaller than the band gap energy of the first intermediate layer mainly by adjusting the composition ratio of Ga and N.

According to one embodiment of the present invention, a nitride semiconductor element is made based on the above-described findings and includes: an n-side nitride semiconductor layer; an active layer provided on the n-side nitride semiconductor layer and including a plurality of well layers formed of a nitride semiconductor and a plurality of barrier layers formed of a nitride semiconductor; and a p-side nitride semiconductor layer provided on the active layer. The plurality of well layers includes in order from the n-side nitride semiconductor layer side: a first intermediate layer having a smaller band gap energy than the barrier layer and containing Al, Ga and N; a second intermediate layer having a smaller band gap energy than the first intermediate layer and containing Ga and N; and a light emitting layer emitting ultraviolet light, having a smaller band gap energy than the first intermediate layer, and containing Ga and N. The thickness of the first intermediate layer is less than the thickness of each of the second intermediate layer and the light emitting layer, and of the plurality of barrier layers, the barrier layer disposed between the second intermediate layer and the light emitting layer is doped with n-type impurities.

### Embodiments

A nitride semiconductor element according to an embodiment and a method of manufacturing a light emitting device including the nitride semiconductor element will be described with reference to the drawings.

### 1. Nitride Semiconductor Element

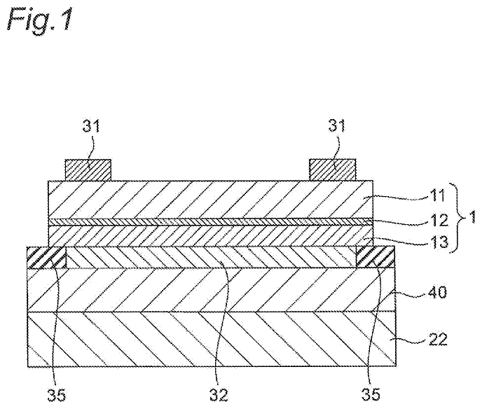

FIG. 1 is a cross-sectional view showing a configuration of a nitride semiconductor element 1 disposed over a second substrate 22, according to the present embodiment.

As shown in FIG. 1, the nitride semiconductor element 1 according to the present embodiment is disposed over the second substrate 22. The nitride semiconductor element 1 includes, in order from the second substrate 22 side, a p-side nitride semiconductor layer 13, an active layer 12, and an n-side nitride semiconductor layer 11. First electrodes 31 are electrically connected to the n-side nitride semiconductor layer 11. A second electrode 32 is electrically connected to the p-side nitride semiconductor layer 13. The nitride semiconductor element 1 is joined to the second substrate 22 via a metal layer 40. This makes it possible to supply power to the nitride semiconductor element 1 via the second substrate 22, for example, by using a semiconductor substrate with conductivity or a substrate made of metal as the second substrate 22. The nitride semiconductor element 1 with such a structure enables the active layer 12 to emit light by applying a voltage between the first electrode 31 and the second electrode 32. The light emitted by the nitride semiconductor element 1 is discharged mainly from a surface of the n-side nitride semiconductor layer 11 on which the first electrodes 31 are provided.

The nitride semiconductor element 1 of the present embodiment will be described in detail below.

### <N-Side Nitride Semiconductor Layer>

The n-side nitride semiconductor layer 11 is formed of, for example, a nitride semiconductor doped with n-type impurities such as Si. The n-side nitride semiconductor layer 11 may be formed by a single layer or alternatively may be formed to include a plurality of layers. The n-side nitride semiconductor layer 11 may partly include, for example, an undoped semiconductor layer. Here, the undoped semiconductor layer refers to a layer grown without adding any n-type impurities during its growth, but may contain, for example, inevitable impurities that are mixed in from an adjacent layer by diffusion or the like.

### <P-Side Nitride Semiconductor Layer>

The p-side nitride semiconductor layer 13 is formed of, for example, a nitride semiconductor doped with p-type impurities such as Mg. The p-side nitride semiconductor layer 13 may be formed of the single layer or alternatively may be formed to include a plurality of layers. The p-side nitride semiconductor layer 13 may partly include, for example, an undoped semiconductor layer.

### <Active Layer>

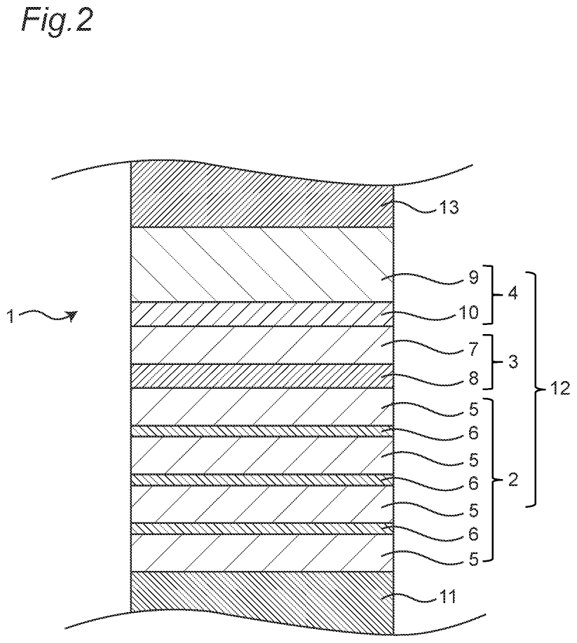

The active layer 12 includes a plurality of well layers formed of a nitride semiconductor and a plurality of barrier layers formed of a nitride semiconductor. As shown in FIG. 2, the multiple quantum well structure according to the present embodiment includes a first layer portion 2, a second layer portion 3, and a third layer portion 4 in order from the n-side nitride semiconductor layer 11 side. The first layer portion 2 includes a plurality of first intermediate layers 6 and a plurality of barrier layers 5. The second layer portion 3 includes a second intermediate layer 8 and an n-type impurity-doped barrier layer 7. The third layer portion 4 includes a light emitting layer 10 and an undoped barrier layer 9 with no impurities doped.

### (First Layer Portion)

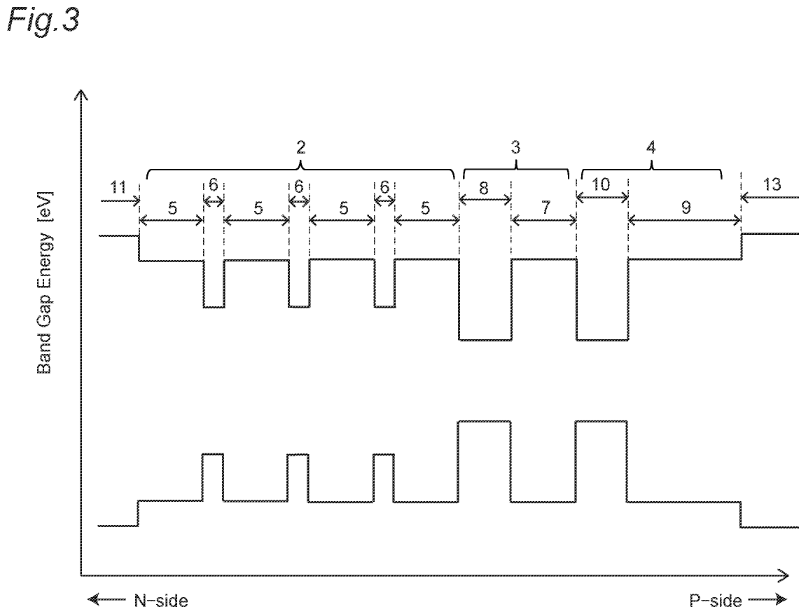

The first layer portion 2 is a portion in which the first intermediate layers 6 and the barrier layers 5 are alternately stacked. The barrier layer 5 is disposed on the n-side nitride semiconductor layer 11, and the first intermediate layer 6 is disposed on the barrier layer 5, followed by the other barrier layers 5 and first intermediate layers 6 alternately stacked on top of each other, with the barrier layer 5 disposed at the uppermost position. The first layer portion 2 according to the embodiment includes four barrier layers 5 and three first intermediate layers 6. As shown in FIG. 3, the barrier layer has a larger band gap energy than the well layer. This can also be applied to the second layer portion 3 and the third layer portion 4 to be described below.

The barrier layer 5 is a nitride semiconductor layer containing Al, Ga, and N. The nitride semiconductor layer 5 containing Al, Ga, and N is made of, for example, a ternary compound. The general formula of the barrier layer 5 is, for example, AlₐGa₁₋ₐN (0<a<1). The mixed crystal ratio of Al in the barrier layer 5 is preferably 0.05≤a≤0.15. The thickness of the barrier layer 5 is, for example, 10 nm or more and 50 nm or less, and preferably 20 nm or more and 40 nm or less. The barrier layer 5 of the first layer portion 2 may be doped with n-type impurities, like the n-type impurity-doped barrier layer 7 of the second layer portion 3 to be described below. Of the plurality of barrier layers 5, some may be barrier layers doped with n-type impurities, while others may be barrier layers not doped with n-type impurities. By doping the barrier layer 5 of the first layer portion 2 with n-type impurities, the recombination probability in the light emitting layer 10 can be enhanced, like the n-type impurity-doped barrier layer 7 of the second layer portion 3 to be described below.

The first intermediate layer 6 is a nitride semiconductor layer containing Al, Ga, and N. As shown in FIG. 3, the first intermediate layer 6 has a larger band gap energy than each of the second intermediate layer 8 and the light emitting layer 10. The first intermediate layer 6 is made of, for example, a ternary or quaternary compound. The general formula of the first intermediate layer 6 is, for example, Al_{b}In_{c}Ga_{1-b-c}N (0<b<1, 0≤c<1, b+c<1). The mixed crystal ratio of Al in the first intermediate layer 6 is preferably 0.03≤b≤0.1. The content of In in the first intermediate layer 6 is preferably 0≤c≤0.03. By forming the first intermediate layer 6 with such a composition, absorption of light emitted from the light emitting layer 10 can be suppressed. Unlike the light emitting layer 10 that emits light, the first intermediate layer 6 is a non-luminescent well layer that does not substantially emit light.

The thickness of the first intermediate layer 6 is less than the thickness of each of the second intermediate layer 8 and the light emitting layer 10. By forming these layers with such thicknesses, the self-absorption of light in the first intermediate layer 6 can be suppressed effectively. The thickness of the first intermediate layer 6 is, for example, 2 nm or more and 10 nm or less, and preferably 3 nm or more and 7 nm or less.

The first intermediate layer 6 having the band gap energy and thickness described above can serve as a buffer layer for growing the light emitting layer 10 with good crystallinity as described below, and can also suppress the absorption of the light emitted from the light emitting layer 10.

### (Second Layer Portion)

The second layer portion 3 is a portion in which one second intermediate layer 8 and one n-type impurity-doped barrier layer 7 are stacked on each other. The second intermediate layer 8 is disposed on the barrier layer 5 stacked at the uppermost portion of the first layer portion 2, and the n-type impurity-doped barrier layer 7 is disposed on the second intermediate layer 8.

The n-type impurity-doped barrier layer 7 in the second layer portion 3 is a nitride semiconductor layer doped with n-type impurities and containing Al, Ga, and N. The n-type impurity-doped barrier layer 7 is made of, for example, a ternary compound. The composition of the n-type impurity-doped barrier layer 7 may be the same as that of the barrier layer 5 described above. The thickness of the n-type impurity-doped barrier layer 7 is, for example, 20 nm or more and 40 nm or less. The n-type impurity is, for example, Si. The concentration of n-type impurities in the n-type impurity-doped barrier layer 7 is, for example, 1×10¹⁷ atoms/cm³ or more and 1×10¹⁹ atoms/cm³ or less. By forming the n-type impurity-doped barrier layer 7 adjacent to the light emitting layer 10, the recombination probability in the light emitting layer 10 between holes injected from the p-side nitride semiconductor layer 13 and electrons injected through the n-type impurity-doped barrier layer 7 can be enhanced, compared to the case where an undoped barrier layer is provided between the first intermediate layer 6 and the second intermediate layer 8. The recombination probability in the light emitting layer 10 can be enhanced, and as a result, the injection of holes into the second intermediate layer 8 and the first intermediate layer 6 can be suppressed, which can obtain the structure in which the second intermediate layer 8 and the first intermediate layer 6 do not substantially emit light.

The second intermediate layer 8 is a nitride semiconductor layer containing Ga and N, and preferably a nitride semiconductor layer containing In, Ga, and N. As shown in FIG. 3, the second intermediate layer 8 has a smaller band gap energy than the first intermediate layer 6. The general formula of the second intermediate layer 8 is, for example, In_{d}Ga_{1-d}N (0≤d<1). The content of In in the second intermediate layer 8 is preferably less than the content of In in the light emitting layer 10. Thus, the band gap energy of the second intermediate layer 8 is made larger than the band gap energy of the light emitting layer 10, thereby making it possible to suppress the absorption by the second intermediate layer 8 of the light emitted from the light emitting layer 10. The content of In in the second intermediate layer 8 is preferably 0≤d≤0.03. Unlike the light emitting layer 10 that emits light, the second intermediate layer 8 is a non-luminescent well layer that does not substantially emit light, as in the first intermediate layer 6 described above.

When the band gap energy of the second intermediate layer 8 is set substantially the same as the band gap energy of the light emitting layer 10, the thickness of the second intermediate layer 8 is preferably less than the thickness of the light emitting layer 10. This can suppress absorption by the second intermediate layer 8 of the light emitted from the light emitting layer 10. By reducing the thickness of the second intermediate layer 8, the self-absorption of light by the second intermediate layer 8 is suppressed. The thickness of the second intermediate layer 8 is greater than that of the first intermediate layer 6. The thickness of the second intermediate layer 8 is, for example, 5 nm or more and 20 nm or less, and preferably 10 nm or more and 18 nm or less.

The second intermediate layer 8 with the band gap energy and thickness described above suppresses the lattice relaxation in crystals caused between the first intermediate layer 6 and the light emitting layer 10 to be described below. Here, the lattice relaxation is a phenomenon in which dislocations are generated in boundaries between crystals with different lattice constants, thereby dispersing strains. Meanwhile, the occurrence of lattice relaxation tends to generate dislocations to reduce crystallinity. In the nitride semiconductor element of the present embodiment, the crystallinity reduced by stacking the first intermediate layer 6 made of a nitride semiconductor containing Al can be restored by providing the second intermediate layer 8.

### (Third Layer Portion)

The third layer portion 4 is a portion in which one light emitting layer 10 and one undoped barrier layer 9 are stacked on each other. The light emitting layer 10 is disposed on the n-type impurity-doped barrier layer 7 of the second layer portion 3, and the undoped barrier layer 9 is disposed on the light emitting layer 10.

The undoped barrier layer 9 in the third layer portion 4 is a nitride semiconductor layer not doped with any n-type impurities. The undoped barrier layer 9 is made of, for example, a ternary compound. The undoped barrier layer 9 may have the same composition as each of the barrier layer 5 and the n-type impurity-doped barrier layer 7 described above. The thickness of the undoped barrier layer 9 is greater than the thickness of each of the barrier layer 5 and the n-type impurity-doped barrier layer 7 described above. The thickness of the undoped barrier layer 9 is, for example, 30 nm or more and 50 nm or less. Since the undoped barrier layer 9 does not contain any n-type impurities, holes moved from the p-side nitride semiconductor layer 13 passes through the undoped barrier layer 9 to move to the light emitting layer 10. Because of this, the holes can be supplied to the light emitting layer 10 efficiently, improving the luminous efficiency of the light emitting layer 10.

The light emitting layer 10 is a nitride semiconductor layer containing Ga and N and that emits ultraviolet light. The ultraviolet light as used in the present specification means light with a wavelength of 400 nm or less. The general formula of the light emitting layer 10 is, for example, InₑGa₁₋ₑN (0≤e<1). The content of In in the light emitting layer 10 is preferably 0≤e≤0.05. The light emitting layer 10 with such a composition emits ultraviolet light. The peak wavelength of light emitted by the light emitting layer 10 is, for example, 365 nm or more and 400 nm or less. Examples of the peak wavelength of the light emitting layer 10 include approximately 365 nm and approximately 385 nm. As shown in FIG. 3, the light emitting layer 10 has, for example, substantially the same band gap energy as the second intermediate layer 8. It is noted that by containing Al or the like in the light emitting layer 10, the peak wavelength of the light emitting layer 10 can also be set in a range of, for example, 250 nm to 365 nm. When the general formula of the light emitting layer 10 is, for example, Al_{f}Ga_{1-f}N (0<f<1), the Al content can be set at the range of 0<f≤0.6.

The thickness of the light emitting layer 10 is greater than or equal to the thickness of the second intermediate layer 8. The thickness of the light emitting layer 10 is, for example, 10 nm or more and 18 nm or less. The light emitting layer 10 with such a thickness can promote the recombination of electrons and holes.

### 2. Method of Manufacturing Light Emitting Device

A method for manufacturing a light emitting device including the nitride semiconductor element of the present embodiment will be described below.

### <First Wafer Preparation Step>

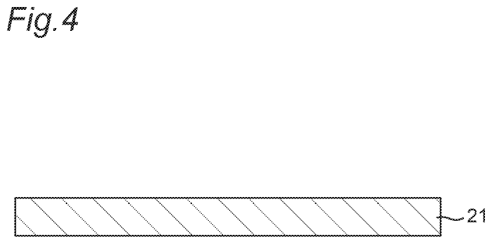

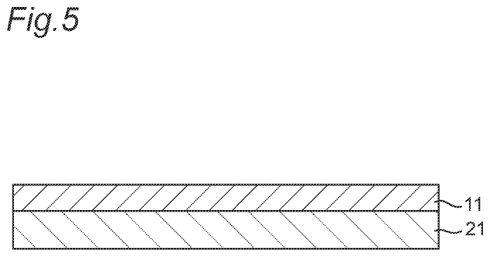

In a first wafer preparation step, as shown in FIG. 4, a first substrate 21 made of, for example, sapphire is prepared. Thereafter, as shown in FIG. 5, for example, an n-type contact layer and an n-type cladding layer are grown on the first substrate 21 to form an n-side nitride semiconductor layer 11 that includes the n-type contact layer and the n-type cladding layer in order from the first substrate 21 side. It is noted that the n-side nitride semiconductor layer 11 may be formed on the first substrate 21 via a buffer layer.

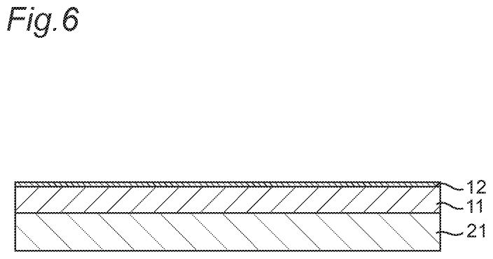

Then, as shown in FIG. 6, the active layer 12 is formed on the n-side nitride semiconductor layer 11. The active layer 12 is formed in the following steps.

First, the barrier layer 5 is grown on the n-side nitride semiconductor layer 11 using a source gas that contains an Al source gas, a Ga source gas and an N source gas (barrier layer growth step). When the composition of the barrier layer 5 is, for example, AlGaN, the barrier layer 5 can be formed by setting the flow rate of the Al source gas in the range of 1 to 2 sccm, the flow rate of the Ga source gas in the range of 30 to 50 sccm, and the flow rate of the N source gas in the range of 5 to 10 sccm.

Then, the first intermediate layer 6 is grown on the barrier layer 5 using a source gas that contains the Al source gas, an In source gas, the Ga source gas, and the N source gas (first intermediate layer growth step). When the composition of the first intermediate layer 6 is, for example, AlInGaN, the first intermediate layer 6 can be formed by setting the flow rate of the Al source gas in the range of 0.2 to 1.5 sccm, the flow rate of the In source gas in the range of 0.1 to 25 sccm, the flow rate of the Ga source gas in the range of 30 to 50 sccm, and the flow rate of the N source gas in the range of 5 to 10 slm.

The first layer portion 2 including a plurality of barrier layers 5 and first intermediate layers 6 is formed by repeatedly performing the barrier layer growth step and the first intermediate layer growth step alternately. It is noted that the step of forming the first layer portion 2 is ended in the barrier layer growth step.

Then, the second intermediate layer 8 is grown on the barrier layer 5 using a source gas that contains the In source gas, the Ga source gas, and the N source gas (second intermediate layer growth step). When the composition of the second intermediate layer 8 is, for example, InGaN, the second intermediate layer 8 can be formed by setting the flow rate of the In source gas in the range of 0.1 to 25 sccm, the flow rate of the Ga source gas in the range of 30 to 50 sccm, and the flow rate of the N source gas in the range of 5 to 10 slm.

Then, the n-type impurity-doped barrier layer 7 is grown on the second intermediate layer 8 using a source gas that contains the Al source gas, the Ga source gas, the N source gas, and an n-type impurity source gas (n-type impurity-doped barrier layer growth step). When the composition of the n-type impurity-doped barrier layer 7 is, for example, AlGaN, and the n-type impurity is Si, the n-type impurity-doped barrier layer 7 can be formed by setting the flow rate of the Al source gas in the range of 1 to 2 sccm, the flow rate of the Ga source gas in the range of 30 to 50 sccm, the flow rate of the N source gas in the range of 5 to 10 slm, and the doping amount of n-type impurities in the range of 1×10¹⁷ atoms/cm³ to 1×10¹⁹ atoms/cm³.

The second layer portion 3 that includes the second intermediate layer 8 and the n-type impurity-doped barrier layer 7 is formed by performing the second intermediate layer growth step and the n-type impurity-doped barrier layer growth step.

Then, the light emitting layer 10 is grown on the n-type impurity-doped barrier layer 7 using the source gas that contains the In source gas, the Ga source gas, and the N source gas (light emitting layer growth step). When the composition of the light emitting layer 10 is, for example, InGaN or GaN, the light emitting layer 10 can be formed by setting the flow rate of the In source gas in the range of 0 to 45 sccm, the flow rate of the Ga source gas in the range of 30 to 50 sccm, and the flow rate of the N source gas in the range of 5 to 10 slm.

Then, the undoped barrier layer 9 is grown on the light emitting layer 10 using a source gas that contains the Al source gas, the Ga source gas and the N source gas (undoped barrier layer growth step). When the composition of the undoped barrier layer 9 is, for example, AlGaN, the undoped barrier layer 9 can be formed by setting the flow rate of the Al source gas in the range of 1 to 2 sccm, the flow rate of the Ga source gas in the range of 30 to 50 sccm, and the flow rate of the N source gas in the range of 5 to 10 slm.

The third layer portion 4 that includes the light emitting layer 10 and the undoped barrier layer 9 is formed by performing the light emitting layer growth step and the undoped barrier layer growth step.

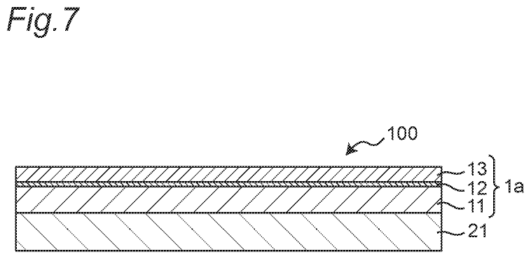

Then, for example, a p-type cladding layer and a p-type contact layer are grown on the active layer 12 including the first layer portion 2, the second layer portion 3, and the third layer portion 4 to form the p-side nitride semiconductor layer 13 that includes the p-type cladding layer and the p-type contact layer in order from the active layer 12 side. Through these steps, as shown in FIG. 7, a first wafer 100, in which a semiconductor structure 1a including the n-side nitride semiconductor layer 11, the active layer 12, and the p-side nitride semiconductor layer 13 is formed on the first substrate 21, is prepared.

### <Second Wafer Preparation Step>

In a second wafer preparation step, the second electrodes 32 with a predetermined pattern are first formed on the p-side nitride semiconductor layer 13 of the first wafer 100, for example, in the following way.

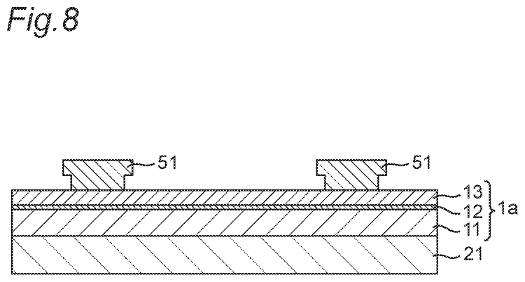

First, as shown in FIG. 8, a resist 51 is formed on the p-side nitride semiconductor layer 13 of the first wafer 100. Here, for example, the resist 51 is formed on portions of the p-side nitride semiconductor layer 13 where the second electrodes are not formed.

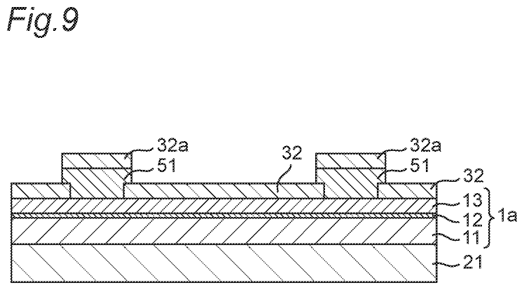

Then, as shown in FIG. 9, a metal film (32, 32a) containing, for example, Ag is formed over the entire upper surface of the p-side nitride semiconductor layer 13. In this way, the second electrodes 32 are formed on the portions of the p-side nitride semiconductor layer 13 where the resist 51 is not formed.

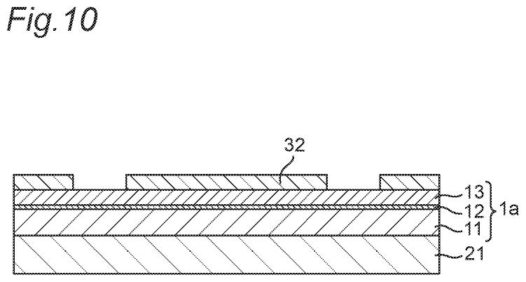

Subsequently, as shown in FIG. 10, the resist 51 is removed together with the metal film 32a formed on the resist 51.

As described above, the second electrodes 32 with the predetermined pattern are formed on the p-side nitride semiconductor layer 13 of the first wafer 100.

Here, a method of forming the second electrode 32 with the predetermined pattern by a lift-off process has been described. However, the second electrodes 32 with the predetermined pattern may be formed without using the lift-off process, for example, by forming a metal film on the entire upper surface of the p-side nitride semiconductor layer 13 without forming the resist 51, forming a resist on the metal film, and then removing portions of the metal film using the resist as a mask.

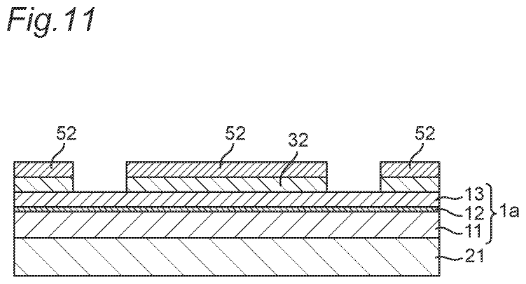

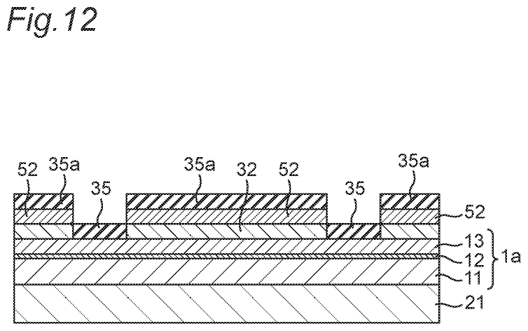

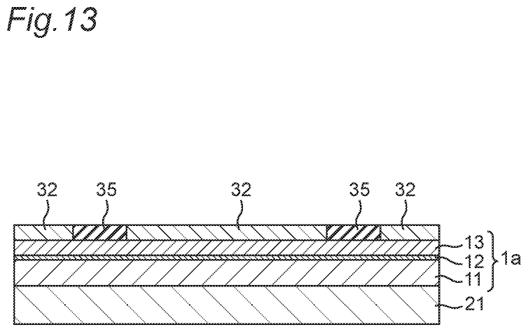

Then, as shown in FIG. 11, a resist 52 is formed on the second electrodes 32. After forming the resist 52, as shown in FIG. 12, an insulating film 35a is formed on portions of the p-side nitride semiconductor layer 13 where the second electrodes 32 are not formed, as well as on the resist 52. Subsequently, as shown in FIG. 13, the resist 52 is removed together with the insulating film 35a formed on the resist 52. In this way, an insulating film 35 is formed on the portions of the p-side nitride semiconductor layer 13 where the second electrodes 32 are not formed. The insulating film 35 is provided, for example, on a cutting position CL to be described below. With this arrangement, the second electrodes 32 can be configured not to be exposed from the side surface of the light emitting device by means of the insulating film 35. As a result, the occurrence of short circuit on the side surface of the light emitting device can be suppressed, thus improving the reliability thereof.

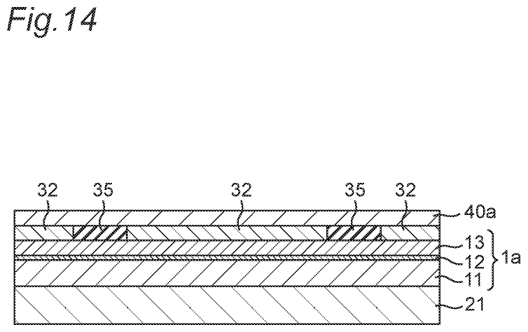

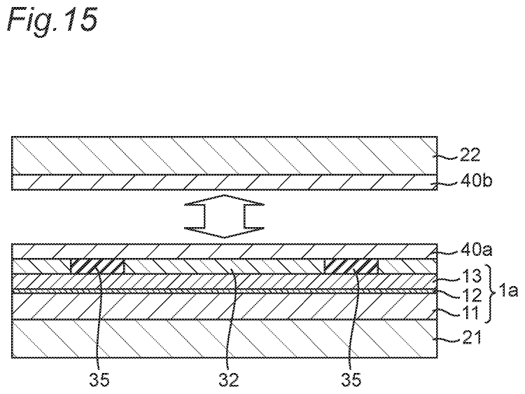

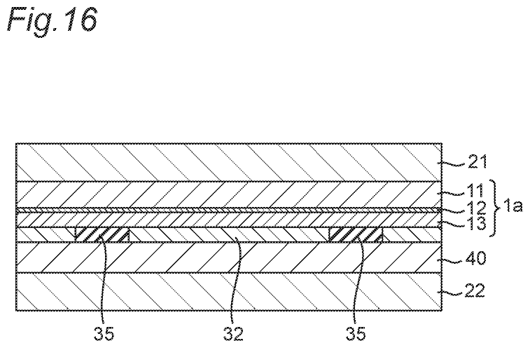

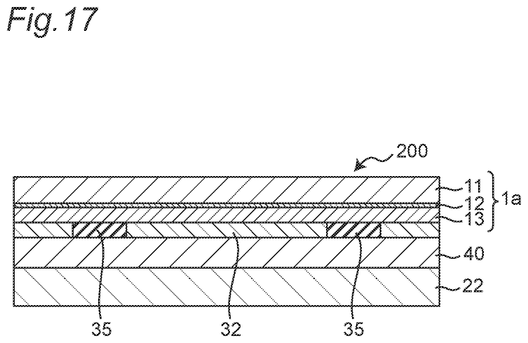

Then, as shown in FIG. 14, a metal layer 40a is formed on the second electrodes 32 formed on the p-side nitride semiconductor layer 13, as well as on the insulating film 35. Separately, as shown in FIG. 15, the second substrate 22 with a metal layer 40b formed on one surface thereof is prepared, and then the metal layer 40b is joined to the metal layer 40a. Consequently, as shown in FIG. 16, the second substrate 22 is joined to the p-side nitride semiconductor layer 13 via the second electrodes 32 and the insulating film 35. After joining the second substrate 22, as shown in FIG. 17, the first substrate 21 is removed. As described above, the second substrate 22 is joined to the p-side nitride semiconductor layer 13 of the first wafer 100, and then the first substrate 21 is removed from the first wafer 100. The removal of the first substrate 21 is performed, for example, by laser lift-off, which involves irradiating an area including and surrounding an interface between the first substrate 21 and the n-side nitride semiconductor layer 11 with laser light to thereby separate the first substrate 21 from the n-side nitride semiconductor layer 11. Alternatively, wet etching which involves removal using a solution capable of etching the first substrate 21 is performed. As described above, the semiconductor structure 1a formed on the first substrate 21 is transferred onto the second substrate 22 via the metal layer 40, the second electrodes 32, and the insulating film 35. In this way, as shown in FIG. 17, a second wafer 200 is prepared. Here, the second wafer 200 includes the semiconductor structure 1a over the second substrate 22 with the n-side nitride semiconductor layer 11 exposed on the surface of the second wafer. That is, in the second wafer 200, the p-side nitride semiconductor layer 13, the active layer 12, and the n-side nitride semiconductor layer 11 are stacked on the second substrate 22 in order from the second substrate 22 side via the metal layer 40, the second electrodes 32, and the insulating film 35. Here, the second substrate 22 is preferably a silicon substrate made of Si. By using a silicon substrate as the second substrate 22, the second substrate 22 can be easily divided in a cutting step to be described below.

### <Nitride Semiconductor Element Separation Step>

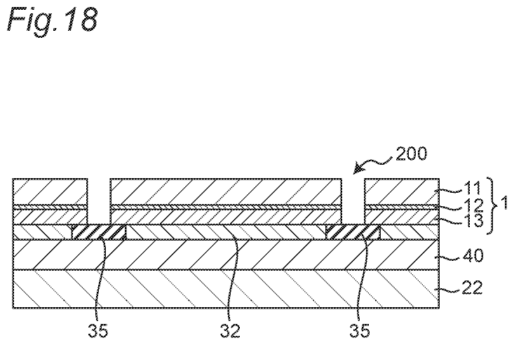

Next, as shown in FIG. 18, portions of the semiconductor structure 1a of the second wafer 200 are removed to separate the second wafer into a plurality of nitride semiconductor elements 1. In this step, the semiconductor structure 1a is separated such that separated portions thereof correspond to respective light emitting devices obtained in the cutting step to be described below. The removal of the portions of the semiconductor structure 1a is performed, for example, by dry etching such as reactive ion etching.

### <First Electrode Formation Step>

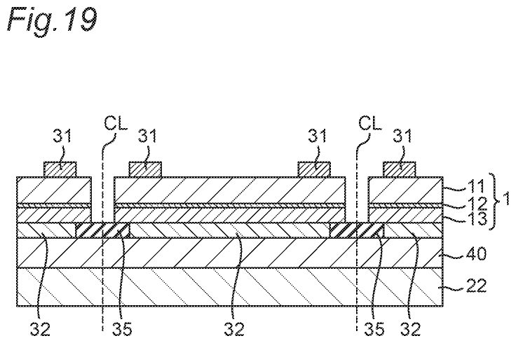

Then, the first electrodes 31 with a predetermined pattern are formed on the n-side nitride semiconductor layer 11 of the second wafer 200 shown in FIG. 19. The first electrode 31 can be formed by a lift-off process or etching process using a resist, in the same way as the method of forming the second electrode 32 described above.

### <Cutting Step>

Finally, the second wafer 200 with the first electrodes 31 formed thereon is divided into individual light emitting devices, each having a desired size. This dividing is performed by dicing or the like along the predetermined cutting position CL shown in FIG. 19.

### 3. Modification of Nitride Semiconductor Element

A modification of the nitride semiconductor element 1 will be described below.

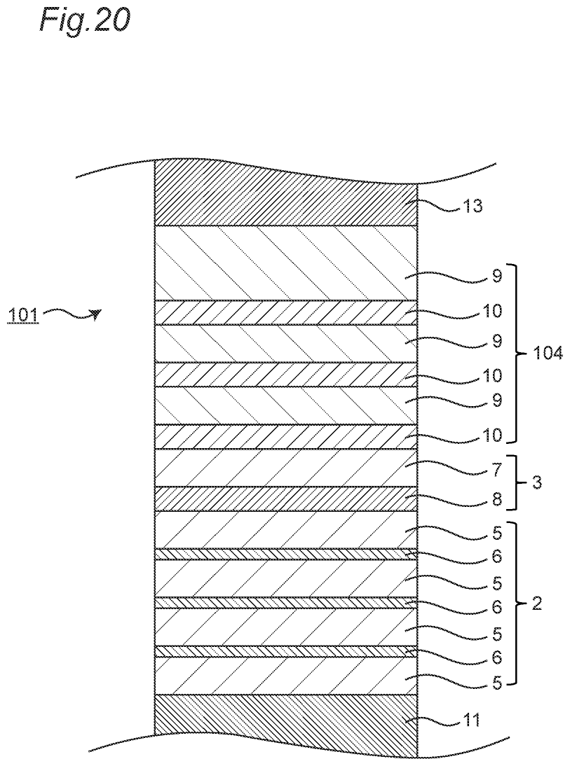

The third layer portion 4 in the nitride semiconductor element 1 of the above-described embodiment includes one light emitting layer 10 and one undoped barrier layer 9, but is not limited to this and may include a plurality of light emitting layers 10 and a plurality of undoped barrier layers 9. For example, as shown in FIG. 20, a nitride semiconductor element 101 of the modification includes the third layer portion 104 including three light emitting layers 10 and three undoped barrier layers 9. Of a plurality of undoped barrier layers 9, an undoped barrier layer 9 provided in contact with the p-side nitride semiconductor layer 13 may be thicker than the other undoped barrier layers 9.

Furthermore, although the first layer portion 2 according to the nitride semiconductor element 1 described above includes the four barrier layers 5 and the three first intermediate layers 6, the number of first intermediate layers 6 included in the first layer portion 2 is not limited thereto. For example, the first layer portion 2 may include one first intermediate layer 6 or may include a plurality of, i.e., two or four or more first intermediate layers 6. The number of barrier layers 5 can also vary depending on the number of first intermediate layers 6.

### EXAMPLE 1

A nitride semiconductor element of Example 1 was fabricated in the following way.

First, the first substrate 21 made of sapphire was prepared. Then, the n-type contact layer and the n-type cladding layer were grown on the first substrate 21 to form the n-side nitride semiconductor layer 11 including the n-type contact layer and the n-type cladding layer in order from the first substrate 21 side.

Then, the barrier layer 5 made of Al_{0.095}Ga_{0.905}N and containing n-type impurities and the first intermediate layer 6 made of Al_{0.03}In_{0.005}Ga_{0.965}N were stacked on the n-side nitride semiconductor layer 11. In this example, four barrier layers 5 and three first intermediate layers 6, each of which was disposed between adjacent barrier layers 5 of the four barrier layers 5, were formed. The barrier layer 5 was grown to a thickness of 29 nm, and the first intermediate layer 6 was grown to a thickness of 5 nm. The flow rate of each source gas when growing the barrier layer 5 was set at the following level: 1.5 sccm for the Al source gas, 38.7 sccm for the Ga source gas, and 7 slm for the N source gas. The n-type impurity contained in the barrier layer 5 was Si, and the doping amount of Si was set at 1×10¹⁸ atoms/cm³. The flow rate of each source gas when growing the first intermediate layer 6 was set at the following level: 0.2 sccm for the Al source gas, 6 sccm for the In source gas, 43.6 sccm for the Ga source gas, and 7 slm for the N source gas.

Then, one second intermediate layer 8 made of In_{0.005}Ga_{0.995}N and one n-type impurity-doped barrier layer 7 made of Al_{0.095}Ga_{0.905}N and containing Si as an n-type impurity were stacked layer by layer on the barrier layer 5. The second intermediate layer 8 was grown to a thickness of 15 nm, and the n-type impurity-doped barrier layer 7 was grown to a thickness of 29 nm. The flow rate of each source gas when growing the second intermediate layer 8 was set at the following level: 16 sccm for the In source gas, 43.6 sccm for the Ga source gas, and 7 slm for the N source gas. The flow rate of each source gas when growing the n-type impurity-doped barrier layer 7 was set at the following level: 1.5 sccm for the Al source gas, 38.7 sccm for the Ga source gas, and 7 slm for the N source gas. The n-type impurity contained in the n-type impurity-doped barrier layer 7 was Si, and the doping amount of Si was set at 1×10¹⁸ atoms/cm³.

Then, one light emitting layer 10 made of In_{0.005}Ga_{0.995}N and one undoped barrier layer 9 made of Al_{0.095}Ga_{0.905}N were stacked layer by layer on the n-type impurity-doped barrier layer 7. The light emitting layer 10 was grown to a thickness of 15 nm, and the undoped barrier layer 9 was grown to a thickness of 40 nm. The flow rate of each source gas when growing the light emitting layer 10 was set at the following level: 16 sccm for the In source gas, 43.6 sccm for the Ga source gas, and 7 slm for the N source gas. The flow rate of each source gas when growing the undoped barrier layer 9 was set at the following level: 1.5 sccm for the Al source gas, 38.7 sccm for the Ga source gas, and 7 slm for the N source gas.

After forming the active layer 12 grown in this way, the p-side nitride semiconductor layer 13 including the p-type cladding layer and the p-type contact layer was formed to prepare the first wafer 100.

Then, the second electrodes 32 with the predetermined pattern were formed on the p-side nitride semiconductor layer 13 of the first wafer 100 and transferred to the second substrate 22 via the metal layer 40. Thereafter, the first substrate 21 was removed to form the first electrodes 31 with the predetermined pattern, on the n-side nitride semiconductor layer 11.

The emission output of the nitride semiconductor element of Example 1 formed as described above was evaluated when a current of 1,000 mA was applied.

As a result, the emission output of the nitride semiconductor element of Example 1 was 1605.4 mW.

### EXAMPLE 2

A nitride semiconductor element of Example 2 was fabricated in the same manner as in the nitride semiconductor element of Example 1 except that the first intermediate layer 6 was grown to a thickness of 8 nm unlike the nitride semiconductor element of Example 1.

The emission output of the nitride semiconductor element of Example 2 fabricated as described above was 1576.0 mW when a current of 1,000 mA was applied.

### EXAMPLE 3

A nitride semiconductor element of Example 3 was fabricated in the same manner as in the nitride semiconductor element of Example 1 except that the second intermediate layer 8 was grown to a thickness of 8 nm unlike the nitride semiconductor element of Example 1. The emission output of the nitride semiconductor element of Example 3 fabricated as described above was 1594.3 mW when a current of 1,000 mA was applied.

### EXAMPLE 4

A nitride semiconductor element of Example 4 was fabricated in the same manner as in the nitride semiconductor element of Example 1 except that the flow rate of each source gas when growing the first intermediate layer 6 was set at the following level: 0.4 sccm for the Al source gas, 6 sccm for the In source gas, 43.6 sccm for the Ga source gas, and 7 slm for the N source gas and that the composition of the first intermediate layer 6 was Al_{0.045}In_{0.005}Ga_{0.95}N unlike the nitride semiconductor element of Example 1.

The emission output of the nitride semiconductor element of Example 4 fabricated as described above was 1614.2 mW when a current of 1,000 mA was applied.

### EXAMPLE 5

A nitride semiconductor element of Example 5 was fabricated in the same manner as in the nitride semiconductor element of Example 1 except that the flow rate of each source gas when growing the first intermediate layer 6 was set at the following level: 0.6 sccm for the Al source gas, 6 sccm for the In source gas, 43.6 sccm for the Ga source gas, and 7 slm for the N source gas and that the composition of the first intermediate layer 6 was Al_{0.06}In_{0.005}Ga_{0.935}N unlike the nitride semiconductor element of Example 1.

The emission output of the nitride semiconductor element of Example 5 fabricated as described above was 1595.6 mW when a current of 1,000 mA was applied.

### REFERENCE EXAMPLE 1

A nitride semiconductor element of Reference Example 1 was fabricated in the same manner as in the nitride semiconductor element of Example 1 except that the first intermediate layer 6 made of In_{0.005}Ga_{0.995}N was grown to a thickness of 15 nm unlike the nitride semiconductor element of Example 1. Here, the flow rate of each source gas when growing the first intermediate layer 6 made of In_{0.005}Ga_{0.995}N was set at the following level: 16 sccm for the In source gas, 43.6 sccm for the Ga source gas, and 7 slm for the N source gas.

The emission output of the nitride semiconductor element of Reference Example 1 fabricated as described above was 1523.2 mW when a current of 1,000 mA was applied.

### REFERENCE EXAMPLE 2

A nitride semiconductor element of Reference Example 2 was fabricated in the same manner as in the nitride semiconductor element of Example 1 except that the second intermediate layer 8 made of Al_{0.03}In_{0.005}Ga_{0.965}N was grown to a thickness of 5 nm unlike the nitride semiconductor element of Example 1. Here, the flow rate of each source gas when growing the second intermediate layer 8 made of Al_{0.03}In_{0.005}Ga_{0.965}N was set at the following level: 0.2 sccm for the Al source gas, 6 sccm for the In source gas, 43.6 sccm for the Ga source gas, and 7 slm for the N source gas.

The emission output of the nitride semiconductor element of Reference Example 2 fabricated as described above was 1572.0 mW when a current of 1,000 mA was applied.

The results of these Examples 1 to 5 and Reference Examples 1 and 2 are shown in Table 1. It is noted that in Table 1, the thickness of the first intermediate layer 6 is denoted as the thickness T1, while the thickness of the second intermediate layer 8 is denoted as the thickness T2.

TABLE 1

| | | | | | | Reference | Reference |
|---|---|---|---|---|---|---|---|
| | Example | Example | Example | Example | Example | Example | Example |
| | 1 | 2 | 3 | 4 | 5 | 1 | 2 |
| Emission | 1605.4 | 1576.0 | 1594.3 | 1614.2 | 1595.6 | 1523.2 | 1572.0 |
| Output [mW] | | | | | | | |
| Thickness | 5 | 8 | 5 | 5 | 5 | 15 | 5 |
| T1 [nm] | | | | | | | |
| Thickness | 15 | 15 | 8 | 15 | 15 | 15 | 5 |
| T2 [nm] | | | | | | | |

These results clearly show that the nitride semiconductor elements of Examples 1 to 5 exhibited a higher emission output than the nitride semiconductor elements of Reference Examples 1 and 2, as the band gap energy of the first intermediate layer 6 was larger than the band gap energy of each of the second intermediate layer 8 and the light emitting layer 10, while the thickness of the first intermediate layer 6 was less than the thickness of each of the second intermediate layer 8 and the light emitting layer 10 in the nitride semiconductor elements of Examples 1 to 5. It is found that further reducing the thickness of the first intermediate layer 6 can obtain the higher emission output. It is also found that the emission output tends to decrease as the amount of Al source gas increases or decreases from a certain value when growing the first intermediate layer 6.

Moreover, it has been found that the nitride semiconductor element of Reference Example 1 in which the composition of each of the first intermediate layer 6 and the second intermediate layer 8 was InGaN had a lower emission output than the nitride semiconductor elements of Examples 1 to 5. This is considered to be due to the fact that the self-absorption by the first intermediate layer 6 in the nitride semiconductor element of Reference Example 1 occurs more than that in the nitride semiconductor element of each of Examples 1 to 5. Furthermore, it has been found that the nitride semiconductor element of Reference Example 2 in which the composition of each of the first intermediate layer 6 and the second intermediate layer 8 was AlInGaN had a lower emission output than the nitride semiconductor elements of Examples 1 to 5. This is considered to be due to the fact that the effect of suppressing the lattice relaxation by the second intermediate layer 8 cannot be obtained.

While embodiments and Examples of the present invention have been described above, the contents of the disclosure may vary in the details of the configuration, and thus the combination of elements, changes in order, and the like in the embodiments and examples may be implemented without departing from the scope and idea of the claimed invention.

### DESCRIPTION OF REFERENCE NUMERALS

1, 101: Nitride semiconductor element
1a: Semiconductor structure
2: First layer portion
3: Second layer portion
4, 104: Third layer portion
5: Barrier layer
6: First intermediate layer
7: n-Type impurity-doped barrier layer
8: Second intermediate layer
9: Undoped barrier layer
10: Light emitting layer
11: n-Side nitride semiconductor layer
12: Active layer
13: p-Side nitride semiconductor layer
21: First substrate
22: Second substrate
31: First electrode
32: Second electrode
35: Insulating film
100: First wafer
200: Second wafer

1. A nitride semiconductor element comprising:
an n-side nitride semiconductor layer;
an active layer located on the n-side nitride semiconductor layer, the active layer comprising a plurality of well layers formed of a nitride semiconductor and a plurality of barrier layers formed of a nitride semiconductor; and
a p-side nitride semiconductor layer located on the active layer; wherein:
the plurality of well layers includes, in order from the n-side nitride semiconductor layer side:
one or more first intermediate layers containing Al, Ga, and N, wherein a band gap energy of each of the one or more first intermediate layers is less than a band gap energy of the barrier layer,
a second intermediate layer containing Ga and N, wherein a band gap energy of the second intermediate layer is less than a band gap energy of each of the one or more first intermediate layers, and
a light emitting layer containing Ga and N and adapted to emit ultraviolet light, wherein a band gap energy of the light emitting layer is less than a band gap energy of each of the one or more first intermediate layers;
a thickness of each of the one or more first intermediate layers is less than a thickness of the second intermediate layer and less than a thickness of the light emitting layer; and
of the plurality of barrier layers, a barrier layer disposed between the second intermediate layer and the light emitting layer is doped with an n-type impurity.

2. The nitride semiconductor element according to claim 1, wherein:
the one or more first intermediate layers comprise a plurality of first intermediate layers.

3. The nitride semiconductor element according to claim 1, wherein:
the band gap energy of the second intermediate layer is substantially the same as the band gap energy of the light emitting layer; and
the thickness of the second intermediate layer is less than the thickness of the light emitting layer.

4. The nitride semiconductor element according to claim 2, wherein:
the band gap energy of the second intermediate layer is substantially the same as the band gap energy of the light emitting layer; and
the thickness of the second intermediate layer is less than the thickness of the light emitting layer.

5. The nitride semiconductor element according to claim 1, wherein:
the light emitting layer and the second intermediate layer contain In; and
the content of In in the second intermediate layer is less than the content of In in the light emitting layer.

6. The nitride semiconductor element according to claim 2, wherein:
the light emitting layer and the second intermediate layer contain In; and
the content of In in the second intermediate layer is less than the content of In in the light emitting layer.

7. The nitride semiconductor element according to claim 3, wherein:
the light emitting layer and the second intermediate layer contain In; and
the content of In in the second intermediate layer is less than the content of In in the light emitting layer.

8. The nitride semiconductor element according to claim 1, wherein:
a composition of each of the one or more first intermediate layers is AlGaN or AlInGaN;
a composition of the second intermediate layer is GaN or InGaN; and
a composition of the light emitting layer is GaN or InGaN.

9. The nitride semiconductor element according to claim 2, wherein:
a composition of each of the one or more first intermediate layers is AlGaN or AlInGaN;
a composition of the second intermediate layer is GaN or InGaN; and
a composition of the light emitting layer is GaN or InGaN.

10. The nitride semiconductor element according to claim 3, wherein:
a composition of each of the one or more first intermediate layers is AlGaN or AlInGaN;
a composition of the second intermediate layer is GaN or InGaN; and
a composition of the light emitting layer is GaN or InGaN.

11. The nitride semiconductor element according to claim 1, wherein:
the thickness of each of the one or more first intermediate layers is 3 nm or more and 7 nm or less;
the thickness of the second intermediate layer is 10 nm or more and 18 nm or less; and
the thickness of the light emitting layer is 10 nm or more and 18 nm or less.

12. The nitride semiconductor element according to claim 2, wherein:
the thickness of each of the one or more first intermediate layers is 3 nm or more and 7 nm or less;
the thickness of the second intermediate layer is 10 nm or more and 18 nm or less; and
the thickness of the light emitting layer is 10 nm or more and 18 nm or less.

13. The nitride semiconductor element according to claim 3, wherein:
the thickness of each of the one or more first intermediate layers is 3 nm or more and 7 nm or less;
the thickness of the second intermediate layer is 10 nm or more and 18 nm or less; and
the thickness of the light emitting layer is 10 nm or more and 18 nm or less.

14. The nitride semiconductor element according to claim 1, wherein:
the barrier layer contains Al, Ga and N.

15. The nitride semiconductor element according to claim 2, wherein:
the barrier layer contains Al, Ga and N.

16. The nitride semiconductor element according to claim 3, wherein:
the barrier layer contains Al, Ga and N.

17. The nitride semiconductor element according to claim 1, wherein:
the thickness of the barrier layer disposed between the second intermediate layer and the light emitting layer is 20 nm or more and 40 nm or less.

18. The nitride semiconductor element according to claim 2, wherein:
the thickness of the barrier layer disposed between the second intermediate layer and the light emitting layer is 20 nm or more and 40 nm or less.

19. The nitride semiconductor element according to claim 3, wherein:
the thickness of the barrier layer disposed between the second intermediate layer and the light emitting layer is 20 nm or more and 40 nm or less.
